(19) United States
(12) Patent Application Publication
(10) Pub. No.: US 2023/0003821 A1
(43) Pub. Date: Jan. 5, 2023

(54) ACCEPTABILITY CHECK METHOD AND CHECK SYSTEM FOR DETECTION TOOLS

(71) Applicant: Changxin Memory Technologies, Inc., Hefei City (CN)

(72) Inventor: Yui-Lang CHEN, Hefei City (CN)

(21) Appl. No.: 17/821,259

(22) Filed: Aug. 22, 2022

Related U.S. Application Data
(63) Continuation of application No. PCT/CN2021/110889, filed on Aug. 5, 2021.

(30) Foreign Application Priority Data
Sep. 10, 2020 (CN) 202010945284.7

(51) Int. Cl. G01R 35/00; G06K 9/62

(52) U.S. Cl. CPC G01R 35/00; G06K 9/6223; H01L 22/26

(57) ABSTRACT

The present application discloses an acceptability check method and check system for detection tools. The check method includes: detecting a plurality of wafers using a detection tool to be checked, to obtain first detection data; detecting the plurality of wafers using an existing detection tool, to obtain second detection data; performing data analysis on the first detection data and the second detection data to obtain category classifications corresponding to the first detection data and the second detection data; and determining whether the first detection data corresponding to the category classification is acceptable; wherein the number of wafers detected using the detection tool to be checked and the number of wafers detected using the existing detection tool are the same.

### CROSS-REFERENCE TO RELATED APPLICATIONS

This application is a continuation application of International Patent Application No. PCT/CN2021/110889, filed on Aug. 5, 2021, which claims priority to Chinese Patent Application No. 202010945284.7, filed with the Chinese Patent Office on Sep. 10, 2020. International Patent Application No. PCT/CN2021/110889 and Chinese Patent Application No. 202010945284.7 are incorporated herein by reference in their entireties.

### TECHNICAL FIELD

The present application relates to the field of semiconductors, and in particular to an acceptability check method and check system for detection tools.

### BACKGROUND

Integrated circuits are a class of micro electronic devices or components. According to such integrated circuits, by utilizing semiconductor manufacturing processes such as oxidation, photoetching, diffusion, epitaxy, masking, sputtering or the like, elements such as transistors, resistors, capacitors, inductors or the like as well as wirings, which are required in a circuit, are interconnected and then fabricated on one or several small semiconductor wafers or dielectric substrates, followed by being encapsulated within a package to attain a microstructure or chip having desired circuit functions.

While an integrated circuit is fabricated, detection is required after a relevant semiconductor process is performed, in order to monitor whether the corresponding semiconductor process satisfies the process requirements. In general, the detection procedure is conducted on a detection tool or a detection apparatus.

To increase production capacity, a new detection tool is usually added to a Fab. The performance of this newly-added detection tool needs to be verified before it is applied to detection, with the aim of determining whether the newly-added detection tool can be used for detection or whether it is acceptable. Currently, whether the newly-added detection tool is acceptable or not is determined by measuring the yield data of wafers that undergo the processes in the newly-added detection tool. This determination procedure has no unified standard or flow and is also highly affected by subjective factors such as processes or personnel, and the accuracy of the check results needs to be improved.

### SUMMARY

The embodiments of the present application provide an acceptability check method and check system for detection tools, enabling standardization of the check procedure and improvement of the accuracy of the check results.

The embodiments of the present application provide an acceptability check method for detection tools, which includes:

detecting a plurality of wafers using a detection tool to be checked, to obtain first detection data;

detecting the plurality of wafers using an existing detection tool, to obtain second detection data;

performing data analysis on the first detection data and the second detection data to obtain category classifications corresponding to the first detection data and the second detection data;

determining whether the first detection data corresponding to the category classification is acceptable;

wherein the number of wafers detected using the detection tool to be checked and the number of wafers detected using the existing detection tool are the same.

Another embodiment of the present application provides an acceptability check system for detection tools, which includes:

a wafer providing circuit, configured to provide wafers;

a detection tool to be checked, configured to detect the plurality of wafers in the detection tool to be checked, to obtain first detection data;

an existing detection tool, configured to detect the plurality of wafers in the existing detection tool, to obtain second detection data;

a data analyzing circuit, configured to perform data analysis on the first detection data and the second detection data to obtain category classifications corresponding to the first detection data and the second detection data; and

a determining circuit, configured to determine whether the first detection data corresponding to the category classification of the detection tool to be checked is acceptable;

wherein the number of wafers detected using the detection tool to be checked and the number of wafers detected using the existing detection tool are the same.

### BRIEF DESCRIPTION OF DRAWINGS

FIG. 1 to FIG. 4 are schematic flow charts of the acceptability check method for detection tools according to the embodiments of the present application;

FIG. 5 to FIG. 9 are schematic structural diagrams of the acceptability check procedure for newly-added detection tools according to the embodiments of the present application; and

FIG. 10 is a schematic structural diagram of the acceptability check system for detection tools according to the embodiments of the present application.

### DESCRIPTION OF EMBODIMENTS

As described in the Background, the existing procedure of determining whether the newly-added detection tools are acceptable has no unified standard or flow and is also highly affected by subjective factors such as processes or personnel, and the accuracy of the check results needs to be improved.

To this end, the embodiments of the present application provide an acceptability check method and check system for detection tools. The check method, after providing a plurality of wafers, includes: detecting the plurality of wafers using a detection tool to be checked, to obtain first detection data; detecting the plurality of wafers using an existing detection tool, to obtain second detection data; performing data analysis on the first detection data and second detection data, to obtain category classifications corresponding to the first detection data and second detection data; and determining whether the first detection data corresponding to the category classifications is acceptable; wherein the number of wafers detected using the detection tool to be checked and the number of wafers detected using the existing detection tool are the same.

Through the foregoing check method, the acceptability check procedure for the detection tool to be checked is standardized and streamlined. In addition, during this check procedure, the second detection data that result from the detection by existing detection tools are taken as original data for the corresponding data analysis and processing, thereby improving the accuracy of the acceptability check results from the detection tool to be checked and the efficiency of the acceptability check procedure of the detection tool to be checked.

In order to make the above objects, features and advantages of the present application more apparent and understandable, the specific implementations of the present application will be described below in detail with reference to the accompanying drawings. When describing the embodiments of the present application in detail, the schematic diagrams attached hereto, for illustrative purposes, are not partially enlarged based on the regular scale, and are not intended to limit the protection scope of the present application but only serve as examples. Besides, the three-dimensional size of length, width and depth should be made clear in practical application.

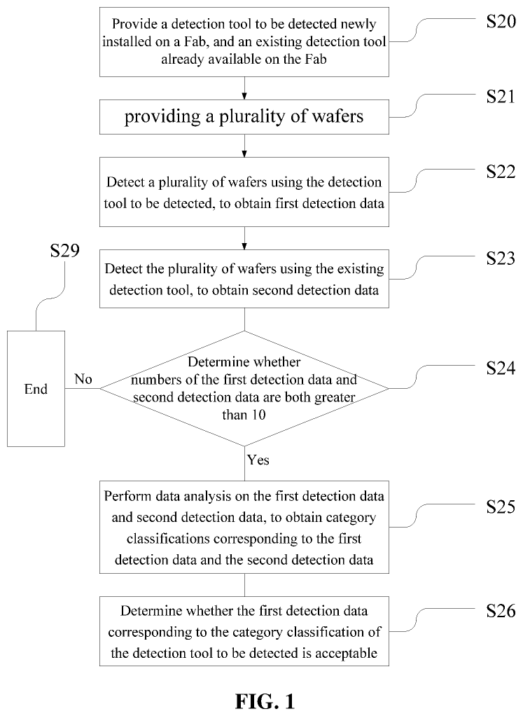

Referring to FIG. 1, an embodiment of the present application provides an acceptability check method for detection tools, which includes the following steps:

S20: providing a detection tool to be checked newly installed on a Fab, and an existing detection tool already available on the Fab;

S21: providing a plurality of wafers;

S22: detecting a plurality of wafers using the detection tool to be checked, to obtain first detection data;

S23: detecting the plurality of wafers using the existing detection tool, to obtain second detection data;

S24: determining whether numbers of the first detection data and second detection data are both greater than 10, if “yes”, executing S25, and if “no”, executing S29 to end the check procedure;

S25: performing data analysis on the first detection data and second detection data, to obtain category classifications corresponding to the first detection data and the second detection data; and

S26: determining whether the first detection data corresponding to the category classification of the detection tool to be checked is acceptable.

In S22 and S23, the number of wafers detected using the detection tool to be checked and the number of wafers detected using the existing detection tool are the same.

The foregoing procedure will be described in details below with reference to the accompanying drawings.

S20 is executed: providing a detection tool to be checked newly installed on a Fab, and an existing detection tool already available on the Fab.

Both the existing detection tool and the newly-installed detection tool to be checked are configured to detect, on the Fab, the wafers undergoing semiconductor manufacturing processes, so as to obtain detection data. The existing detection tool has already been applied on the Fab, with its various performances and yield meeting the process requirements. The newly-installed detection tool to be checked is a device the check for which is required, and their acceptability needs to be determined. As a result, this detection tool has not yet been put into production.

The semiconductor manufacturing processes are oxidation, deposition, photoetching, diffusion, epitaxy, masking, implantation, sputtering and other such semiconductor manufacturing processes.

The parameters of the existing detection tool and the newly-installed detection tool to be checked for detection include a first type (i.e., data obtained from a first test item) and a second type (i.e., data obtained from a second test item). The first type refers to electrical parameter detection when the detection current is alternating current (AC), while the second type refers to electrical parameter detection when the detection current is direct current (DC). Under the first and second types, there are several corresponding test items, with each test item having several specific detection data corresponding thereto. In this embodiment, the existing detection tool and the newly-installed detection tool to be checked are detection tools with the same functions.

S21 is executed: providing a plurality of wafers.

The wafers are those that need to be detected after the corresponding semiconductor manufacturing process is performed on a particular semiconductor process device. The semiconductor process device is a photoetching device (for photolithography), a furnace tube device (for oxidation or annealing process), a deposition device (for deposition process), a sputtering device (for sputtering process), a chemical mechanical polishing device (for chemical mechanical polishing process), an ion implantation device (for implantation process) or other semiconductor process devices.

According to researches, multiple detection tools of certain types can obtain detection data with a higher precision when detecting the same wafer (for example, two detection tools having the same functions can obtain detection data by detecting the same wafer to be detected), whereas multiple detection tools of some other types obtain detection data with a lower precision when detecting the same wafer (the detection procedure will cause damage to a structure to be detected which is formed on the wafer). To improve the detection precision, multiple detection tools are required to detect different wafers.

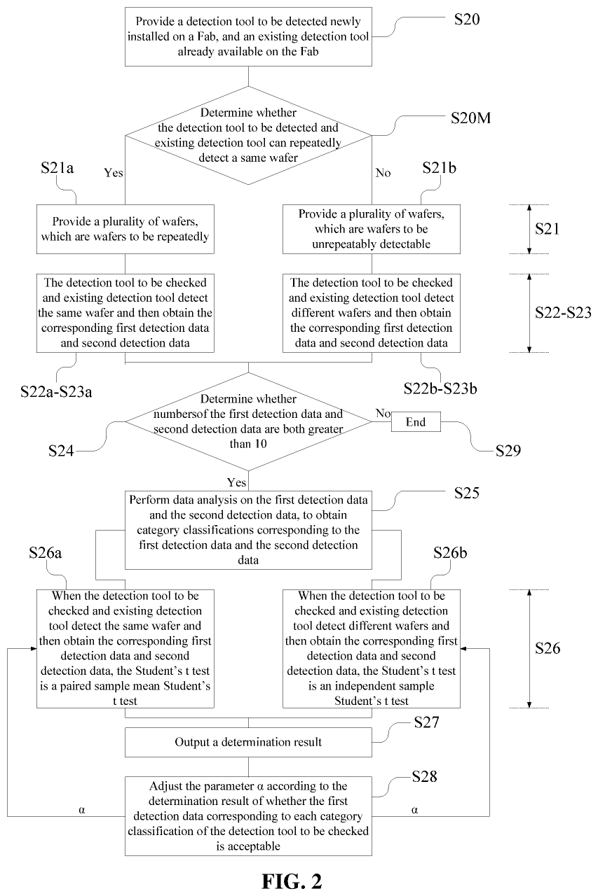

Thus, in an embodiment, to realize a better accuracy of the results obtained from the acceptability check method for detection tools according to the present application, referring to FIG. 2, S20M needs to be executed prior to S21: determining whether the detection tool to be checked and existing detection tool can repeatedly detect a same wafer, if “yes”, executing S21a: providing a plurality of wafers, which are wafers to be repeatedly detectable, and if “no”, executing S21b: providing a plurality of wafers, which are wafers to be unrepeatably detectable. As a consequence, it can be precisely determined whether the newly-installed detection tools to be checked of different types are acceptable, during the subsequent acceptability check procedure for the detection tools to be checked. Both S21a and S21b are a part of S21. It is to be noted that the wafers may not be distinguished in other embodiments.

Whether or not the detection tool to be checked and the existing detection tool can repeatedly detect the same wafer may be directly set in the detection tool to be checked and the existing detection tool, and this setting is directly read at the time of detection. Alternatively, such setting may also be done by an engineer during detection.

In an embodiment, the number of the wafers to be repeatedly detectable is greater than 10 and the number of the wafers to be unrepeatably detectable is greater than 20, which accordingly increases the number of valid samples of the yield data obtained later.

With continued reference to FIG. 1, S22 is executed: detecting at least a part of the wafers in the detection tool to be checked, to obtain first detection data; and S23 is executed: detecting at least a part of the wafers in the existing detection tool, to obtain second detection data.

During detection, one first detection data or one second detection data is obtained by detecting one wafer, and first detection data or second detection data are obtained by detecting a plurality of wafers.

Each of the first detection data and each of the second detection data may be obtained by measuring the same wafer (e.g., the detection tool to be checked detects one wafer and then obtains one first detection data, and the existing detection tool detects the same wafer and then obtains one second detection data), or by measuring different wafers (e.g., the detection tool to be checked detects the first wafer and then obtains one first detection data, and the existing detection tool detects the second wafer and then obtains one second detection data).

In a specific embodiment, referring to FIG. 2, while S22 to S23 are executed, S22a to S23a may be executed for different types of detection devices after S21a (the detection tool to be checked and existing detection tool detect the same wafer and then obtain the corresponding first detection data and second detection data, and in particular, the detection tool to be checked and existing detection tool may detect in sequence all the wafers and then obtain first detection data and second detection data), or S22a to S23a may be executed after S21b (the detection tool to be checked and existing detection tool detect different wafers and then obtain the corresponding first detection data and second detection data, and in particular, all the wafers are divided into a first portion of wafers and a second portion of wafers; the detection tool to be checked detects the first portion of wafers and then obtains first detection data, and the existing detection tool detects the second portion of wafers and then obtains second detection data).

According to researches, there are different types and different items with respect to the data obtained from the detection by the detection tools, so in an embodiment, detecting the plurality of wafers includes: a first test item in which an alternating current is utilized as a detecting current for electrical parameter detection; and a second test item in which a direct current is utilized as the detecting current for electrical parameter detection; wherein the first detection data and the second detection data are test item data of the same test item.

Subsequently it can thus be determined whether or not each of the test item data is acceptable. As a result, whether the detection tool to be checked is acceptable or not can be judged in a comprehensive way, and the accuracy of the acceptability check method for detection tools can be further improved. In an embodiment, prior to S25, S24 is further included: determining whether numbers of the first detection data and second detection data are both greater than 10, if “yes”, executing S25, and if “no”, executing S29 to end the check procedure.

The purpose of executing S24 is to ensure that there are sufficient samples for the subsequent data analysis in step S25, and to improve the accuracy of data analysis. In other embodiments, S25 may also be executed directly without executing S24.

With continued reference to FIG. 1, S25 is executed: performing data analysis on the first detection data and the second detection data, to obtain category classifications corresponding to the first detection data and the second detection data.

A Data Analysis Method Based on Fuzzy System Models (DA-FSM) is used as the method for data analysis of the first detection data and the second detection data.

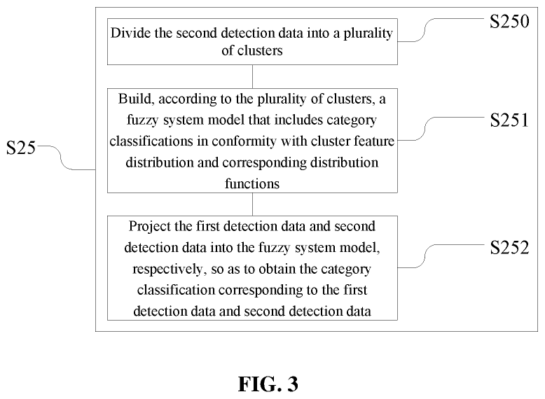

In an embodiment, referring to FIG. 3, S25 may specifically include: S250: dividing the second detection data into a plurality of clusters; S251: building, according to the plurality of clusters, a fuzzy system model that includes category classifications in conformity with cluster feature distribution and corresponding distribution functions, the fuzzy system model being one of a model α, a model β and a model γ, the model α including three category classifications and three corresponding distribution functions, the three category classifications being a low category, a medium category and a high category, the model β including two category classifications and two corresponding distribution functions, the two category classifications being a slightly lower category and a slightly higher category, the model γ including one category classification and one corresponding distribution function, and the one category classification being an overall category; and S252: projecting the first detection data and second detection data into the fuzzy system model, respectively, so as to obtain the category classification corresponding to each of the first detection data and second detection data.

In particular, in S250, the second detection data may be divided into a plurality of clusters using a K-Means clustering algorithm or other grouping or clustering algorithms.

In an embodiment, a description is given with reference to the example of using the K-Means clustering algorithm to divide the second detection data into a plurality of clusters, and the following steps are included:

(1) the second detection data are set as one point set S, which needs to be divided into N categories or clusters, and N is set as required;

(2) K is set to be equal to N and N points are randomly chosen as initial center points;

(3) the distances from each point to these N center points are calculated, the closest center point is chosen and then included into a group centered in this center point;

(4) the center points of the N new clusters are recalculated; and

(5) the K-Means procedure ends, provided that the center points remain unchanged. Otherwise, steps (3) and (4) are repeated.

In the present application, the second detection data are divided at most into 3 clusters, e.g., 3 clusters, 2 clusters, or 1 cluster. Thus, the efficiency of building the fuzzy system model later may be increased, and with the built fuzzy system model, the detection tool to be checked and the category classifications for the second detection data can be reflected in a relatively simple and accurate way. In other embodiments, the second detection data may be divided into more clusters.

In an embodiment, a description is given with reference to the example that the value K is equal to 3. Referring to FIG. 5, the uppermost drawing in FIG. 5 is a graph showing distribution of the second detection data, where the abscissa represents the detection data (the second detection data) and the ordinate represents the number. The middle drawing in FIG. 5 is a distribution diagram of 3 clusters after the K-Means clustering algorithm, where the abscissa represents the detection data and the ordinate represents the number, and 3 clusters have 3 center points corresponding thereto, i.e., C1, C2, and C3.

With continued reference to FIG. 3, S251 is executed: building, according to the a plurality of clusters, a fuzzy system model that includes category classifications in conformity with cluster feature distribution and corresponding distribution functions. While the fuzzy system model is built, the number of the category classifications and the number of the corresponding distribution functions are determined from the number of the clusters, e.g., in the case of 3 clusters, there are 3 category classifications and 3 corresponding distribution functions. In an embodiment, the fuzzy system model is one of a model α, a model β and a model γ, the model α includes three category classifications and three corresponding distribution functions, the three category classifications are a low category, a medium category and a high category, the model β includes two category classifications and two corresponding distribution functions, the two category classifications are a slightly lower category and a slightly higher category, the model γ includes one category classification and one corresponding distribution function, and the one category classification is an overall category. In particular, the fuzzy system model is built as the model α when the second detection data are divided into 3 clusters in S250, the fuzzy system model is built as the model β when the second detection data are divided into 2 clusters in S250, and the fuzzy system model is built as the model γ when the second detection data are divided into 1 cluster in S250.

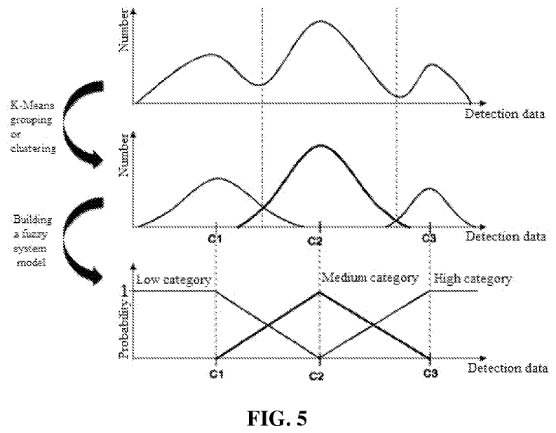

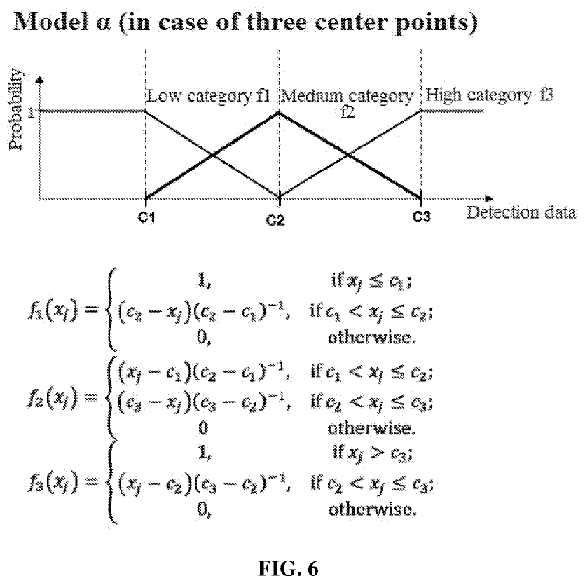

In an embodiment, with reference to FIG. 5, the lowermost drawing in FIG. 5 is a broken line graph showing distribution of the second detection data obtained from the built fuzzy system model, where the abscissa represents the detection data (the second detection data) and the ordinate represents the probability. The category classifications in conformity with cluster feature distribution and the corresponding distribution functions in the fuzzy system model may be obtained in accordance with this broken line graph as well as three center points C1, C2, and C3. In particular, referring to FIG. 6, FIG. 6 is a schematic structural diagram characterizing the model α. The model α is a fuzzy system model that is built when the second detection data are divided into 3 clusters. The model α includes three category classifications and three corresponding distribution functions. The three category classifications are a low category f1, a medium category f2 and a high category f3, and are corresponding to three distribution functions f1(xj), f2(xj) and f3(xj). C1, C2 and C3 represent the yield values corresponding to three center points, and xj represents the detection data variable.

In another embodiment, referring to FIG. 7, FIG. 7 is a schematic structural diagram characterizing the model β. The model β is a fuzzy system model that is built when the second detection data are divided into 2 clusters. The model β includes two category classifications and two corresponding distribution functions. The two category classifications are a slightly lower category f4 and a slightly higher category f5, and are corresponding to two distribution functions f4(xj) and f5(xj). C1 and C2 represent the yield values corresponding to two center points, and xj represents the detection data variable.

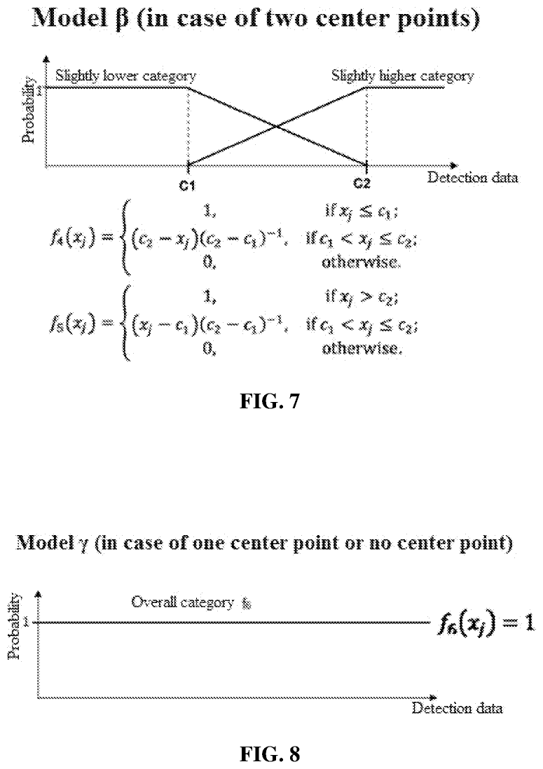

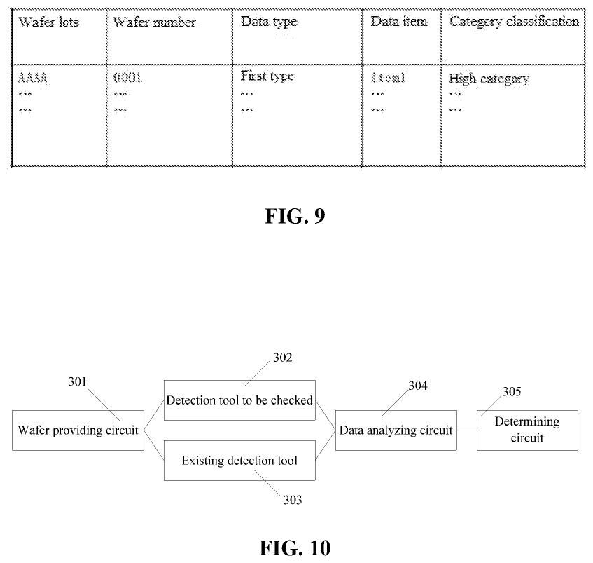

In another embodiment, referring to FIG. 8, FIG. 8 is a schematic structural diagram characterizing the model γ. The model γ is a fuzzy system model that is built when the second detection data are divided into 1 cluster. The model γ includes one category classification and one corresponding distribution function. The one category classification is an overall category f6, and is corresponding to one distribution function f6(xj). xj represents the detection data variable.

In S252, the first detection data and second detection data are projected into the fuzzy system model, respectively, so as to obtain the category classification corresponding to each of the first detection data and each of the second detection data. In particular, the several first detection data and second detection data are respectively projected into one of the model α, the model β or the model γ, so as to obtain the category classification corresponding to each of the first detection data and each of the second detection data. The corresponding category classification is the one corresponding to a particular distribution function when a probability maximum is obtained from calculation of this distribution function. For example, when the first detection data and second detection data are respectively projected into the model α, the first detection data and second detection data are sequentially projected, as the variable xj, into the distribution functions f1(xj), f2(xj) and f3(xj) shown in FIG. 6, to obtain corresponding probabilities. If the probability obtained from calculation of the distribution function f1(xj) is the largest one, then the category classification corresponding to the first detection data or second detection data is the “low category”; if the probability obtained from calculation of the distribution function f2(xj) is the largest one, then the category classification corresponding to the first detection data or second detection data is the “medium category”, and if the probability obtained from calculation of the distribution function f3(xj) is the largest one, then the category classification corresponding to the first detection data or second detection data is the “high category”. The procedure of projecting the first detection data and second detection data respectively into the model β or the model γ so as to obtain the category classification corresponding to each of the first detection data and each of the second detection data is similar to the procedure of projecting into the model α so as to obtain the category classification corresponding to each of the first detection data and each of the second detection data.

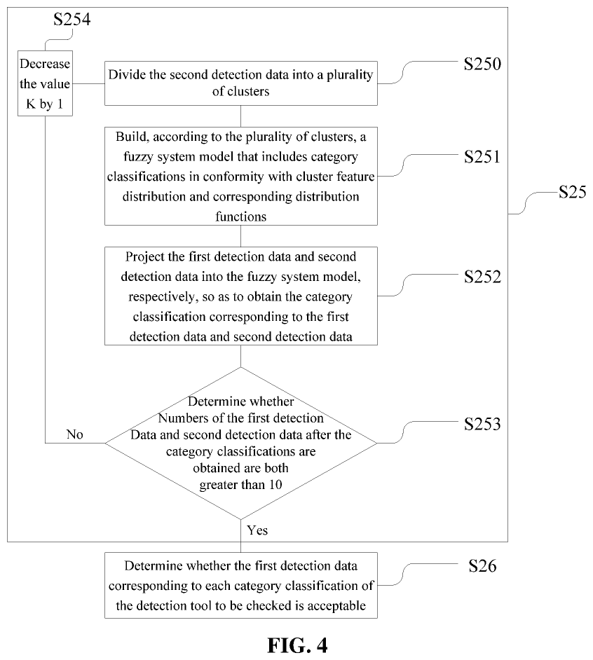

In an embodiment, to further improve the accuracy of the obtained category classification corresponding to each of the first detection data and each of the second detection data and accordingly improve the accuracy of the acceptability check results from the detection tool to be checked, referring to FIG. 4, when dividing the several second detection data into a plurality of clusters in S250, a value K in the K-Means clustering algorithm is preset to be equal to 3, and then the several second detection data are divided into 3 clusters through the K-Means clustering algorithm; at the time of execution of S251, a fuzzy system model is built according to the 3 clusters, the fuzzy system model is a model α and includes category classifications in conformity with cluster feature distribution and corresponding distribution functions, and at the time of execution of S252, several first detection data and second detection data are projected into the model α, respectively, so as to obtain the category classification corresponding to each of the first detection data and each of the second detection data; S253 is executed: determining whether numbers of the first detection data and second detection data after the category classifications are obtained are both greater than 10, if “yes”, executing S26 to determine whether the first detection data corresponding to each category classification of the detection tool to be checked is acceptable, and if “no”, executing S254 to decrease the value K by 1; then, when the value K is equal to 2, continue to execute S250: dividing the second detection data into 2 clusters through the K-Means clustering algorithm; then, S251 is executed: building, according to the 2 clusters, a fuzzy system model, which is the model β; then, S252 is executed: projecting the first detection data and second detection data into the model β, respectively, so as to obtain the category classification corresponding to each of the first detection data and each of the second detection data; then, S253 is executed: continuing to determine whether the numbers of the first detection data and second detection data after the category classifications are obtained are both greater than 10, if “yes”, executing S26 to determine whether the first detection data corresponding to each category classification of the detection tool to be checked is acceptable, and if “no”, executing S254 to decrease the value K by 1; then S250 is executed: dividing the second detection data into 1 cluster through the K-Means clustering algorithm when the value K is equal to 1; then, S251 is executed: building, according to the 1 cluster, a fuzzy system model, which is the model γ; and S252 is executed: projecting first detection data and second detection data into the model γ, respectively, so as to obtain the category classification corresponding to each of the first detection data and each of the second detection data, and directly executing the step of determining whether the first detection data corresponding to each category classification of the detection tool to be checked is acceptable.

In an embodiment, when one of the first detection data and second detection data is of the first type, or the first detection data and second detection data is a certain corresponding test item data under the second type, the step of obtaining the category classification corresponding to each of the first detection data and each of the second detection data includes: obtaining the category classification corresponding to each test item data under the first and second types. In an embodiment, the fuzzy system model corresponding to each test item data is stored.

After the category classifications of the first detection data and the second detection data are obtained, the category classifications of the first detection data and the second detection data may be stored in a table in association with wafer lots, wafer numbers, data types (including the first type and the second type) and data items (item1 or the like).

With continued reference to FIG. 1, S26 is executed: determining whether the first detection data corresponding to each category classification of the detection tool to be checked is acceptable.

In an embodiment, the step of determining whether the first detection data corresponding to each category classification of the detection tool to be checked is acceptable includes: determining whether each test item data under the first and second types of the detection tool to be checked is acceptable, such that it can be checked more precisely whether or not the new tools of different types are acceptable.

A Student's t test is employed to determine whether the first detection data corresponding to each category classification of the detection tool to be checked is acceptable.

In an embodiment, at the time of execution of S26, S26a or S26b is executed respectively, depending on different types of the detection devices. When the detection tool to be checked and existing detection tool detect the same wafer and then obtain the corresponding first detection data and second detection data, the Student's t test is a paired sample mean Student's t test.

At the time of execution of S26b, when the detection tool to be checked and existing detection tool detect different wafers and then obtain the corresponding first detection data and second detection data, the Student's t test is an independent sample Student's t test. Therefore, it can be checked whether or not different types of detection tools are acceptable, and further the precision of the resultant detection results is enhanced.

The sample mean Student's t test and the independent sample Student's t test employ a two-sided test, with a statistical significance level of α=0.05, and two hypothesis tests: H0: the first detection data are significantly different from the second detection data, and H1: there is no significant difference between the first detection data and the second detection data. The Student's t test will produce one of the results (support H0 but reject H1) and (support H1 but reject H0). If H0 is supported but H1 is rejected, it means that our first hypothesis H0 (the presence of a significant difference) is proved to be correct, i.e., there is a significant difference between the first detection data and the second detection data and the first detection data corresponding to the detection tool to be checked is unacceptable. On the contrary, if the hypothesis H1 is supported, then there is no significant difference between the first detection data and the second detection data and the first detection data corresponding to the detection tool to be checked is acceptable.

In an embodiment, the statistical significance level value a may be set in accordance with relevant steps, which specifically include: S1: randomly dividing second detection data into two groups; S2: taking one of the groups as the sample data of the detection tool to be checked (equivalent to obtaining the first detection data by means of measurement) and the other group as the sample data of the existing detection tool (equivalent to obtaining the second detection data by means of measurement); S3: implementing the procedure when the unrepeatable wafers are detected, and obtaining a value p corresponding to each item; and S4: setting the value α for each item as max (value p, τ), where τ is the minimal acceptable significance level value and τ≥1.

In an embodiment, referring to the drawings, S27 is further included subsequent to the Student's t test: outputting a determination result.

The determination result includes “acceptable” or “unacceptable”. In a specific embodiment, the determination result indicates that each test item under the first and second types is “acceptable” and “unacceptable”.

The determination result may also include: type and item to which each test item data belongs, category classification, and corresponding values p and α.

In the specific embodiment, the determination result may be displayed on a user terminal in the form of a table, an icon or a graph, enabling users to acquire the detection results in an intuitive manner.

In an embodiment, S28 is further included: adjusting the statistical significance level value α according to the determination result of whether the first detection data corresponding to each category classification of the detection tool to be checked is acceptable, and performing the Student's t test again. Thus, the stringency in working out the items can be regulated.

In the specific embodiment, the statistical significance level value a may be adjusted and the Student's t test may be performed again, when the detection item data are unacceptable.

The statistical significance level value a may be adjusted artificially based on experience. In particular, the statistical significance level value a may be adjusted on the user terminal, and following this adjustment, the adjusted value a is fed back in order to execute S26 on the basis of the adjusted value a.

The embodiments of the present application also provide an acceptability check system for detection tools, which, with reference to FIG. 10, includes:

a wafer providing circuit 301, configured to provide wafers;

a detection tool to be checked 302, configured to detect a plurality of wafers in the detection tool to be checked, to obtain first detection data;

an existing detection tool 303, configured to detect a plurality of wafers in the existing detection tool, to obtain second detection data;

a data analyzing circuit 304, configured to perform data analysis on the first detection data and second detection data, to obtain category classifications corresponding to the first detection data and second detection data; and

a determining circuit 305, configured to determine whether the first detection data corresponding to each category classification of the detection tool to be checked is acceptable.

the number of wafers detected using the detection tool to be checked and the number of wafers detected using the existing detection tool are the same.

In particular, the wafers are repeatable wafers, the detection tool to be checked and existing detection tool detect the same wafer and then obtain the corresponding first detection data and second detection data.

In an embodiment, the wafers are unrepeatable wafers, the detection tool to be checked and existing detection tool detect different wafers and then obtain the corresponding first detection data and second detection data.

In an embodiment, the first detection data includes several corresponding test data under the first and second types.

In an embodiment, the second detection data includes several corresponding test data under the first and second types

A Data Analysis Method Based on Fuzzy System Models is used as the method for data analysis of the first detection data and the second detection data by the data analyzing circuit 304.

In an embodiment, the procedure of performing data analysis on the first detection data and second detection data to obtain category classifications corresponding to the first detection data and the second detection data by the data analyzing circuit 304 includes: dividing the second detection data into a plurality of clusters; building, according to the plurality of clusters, a fuzzy system model that includes category classifications in conformity with cluster feature distribution and corresponding distribution functions, the fuzzy system model being one of a model α, a model β and a model γ, the model α including three category classifications and three corresponding distribution functions, the three category classifications being a low category, a medium category and a high category, the model β including two category classifications and two corresponding distribution functions, the two category classifications being a slightly lower category and a slightly higher category, the model γ including one category classification and one corresponding distribution function, and the one category classification being an overall category; and projecting first detection data and second detection data into the fuzzy system model, respectively, so as to obtain the category classification corresponding to each of the first detection data and each of the second detection data.

In an embodiment, the data analyzing circuit 304 obtaining the category classification corresponding to each of the first detection data and each of the second detection data includes: obtaining the category classification corresponding to each test item data under the first and second types.

In an embodiment, the determining circuit 305 being configured to determine whether the first detection data corresponding to each category classification of the detection tool to be checked is acceptable includes: determining whether each test item data under the first and second types of the detection tool to be checked is acceptable.

In an embodiment, the data analyzing circuit 304 divides the second detection data into a plurality of clusters using a K-Means clustering algorithm.

In an embodiment, a data sample number determining circuit is further included, which is configured to: determine, before the data analyzing circuit 304 divides the second detection data into a plurality of clusters, whether numbers of the first detection data and second detection data are both greater than 10, if “yes”, execute the step of dividing the second detection data into a plurality of clusters, and if “no”, end the check flow.

In an embodiment, the procedure of dividing into a plurality of clusters, building the fuzzy system model and obtaining the category classification corresponding to each of the first detection data and each of the second detection data by the data analyzing circuit 304 includes: when dividing the second detection data into a plurality of clusters, presetting a value K in the K-Means clustering algorithm to be equal to 3, and then dividing the second detection data into 3 clusters through the K-Means clustering algorithm; building, according to the 3 clusters, a fuzzy system model, which is a model α; projecting the first detection data and second detection data into the model α, respectively, so as to obtain the category classification corresponding to each of the first detection data and each of the second detection data; determining whether numbers of the first detection data and second detection data after the category classifications are obtained are both greater than 10, if “yes”, executing the step of determining whether the first detection data corresponding to each category classification of the detection tool to be checked is acceptable, and if “no”, decreasing the value K by 1; then, when the value K is equal to 2, dividing the second detection data into 2 clusters through the K-Means clustering algorithm; building, according to the 2 clusters, a fuzzy system model, which is the model β; projecting the first detection data and second detection data into the model β, respectively, so as to obtain the category classification corresponding to each of the first detection data and each of the second detection data; based on the category classification corresponding to each of the first detection data and each of the second detection data, continuing to determine whether the numbers of the first detection data and second detection data after the category classifications are obtained are both greater than 10, if “yes”, executing the step of determining whether the first detection data corresponding to each category classification of the detection tool to be checked is acceptable, and if “no”, decreasing the value K by 1; dividing the second detection data into 1 cluster through the K-Means clustering algorithm when the value K is equal to 1; building, according to the 1 cluster, a fuzzy system model, which is the model γ; projecting the first detection data and second detection data into the model γ, respectively, so as to obtain the category classification corresponding to each of the first detection data and each of the second detection data, and directly executing the step of determining whether the first detection data corresponding to each category classification of the detection tool to be checked is acceptable.

In an embodiment, the determining circuit 305 uses a Student's t test to determine whether the first detection data corresponding to each category classification of the detection tool to be checked is acceptable.

In an embodiment, when the detection tool to be checked and existing detection tool detect the same wafer and then obtain the corresponding first detection data and second detection data, a paired sample mean Student's t test is used as the Student's t test by the determining circuit.

In an embodiment, when the detection tool to be checked and existing detection tool detect different wafers and then obtain the corresponding first detection data and second detection data, an independent sample Student's t test is used as the Student's t test by the determining circuit.

In an embodiment, a feedback circuit is further included, which is configured to adjust the statistical significance level value a according to the determination result of whether the first detection data corresponding to each category classification of the detection tool to be checked is acceptable, and to perform the Student's t test again.

It shall be noted that the definition or description of the same or similar sections in this embodiment (check system) as in the previous embodiment (check system) will not be given in this embodiment. Reference is made to the definition or description of the corresponding sections in the previous embodiment.

Although the present application has been disclosed as above in the preferred embodiments, the present application should not be limited by those embodiments. Any skilled in the art may make possible changes or modifications to the technical solutions of the present application by use of the methods and technical content disclosed above without departing from the spirit and scope of the present application. Therefore, any simple alterations, equivalent changes and modifications made to the foregoing embodiments based on the technical essence of the present application without departing from the technical solutions proposed in the present application are deemed to fall within the protection scope of the technical solutions in the present application.

What is claimed is:

1. An acceptability check method for detection tools, comprising:
detecting a plurality of wafers using a detection tool to be checked, to obtain first detection data;
detecting the plurality of wafers using an existing detection tool, to obtain second detection data;
performing data analysis on the first detection data and the second detection data to obtain category classifications corresponding to the first detection data and the second detection data; and
determining whether the first detection data corresponding to the category classification is acceptable;
wherein the number of wafers detected using the detection tool to be checked and the number of wafers detected using the existing detection tool are the same.

2. The acceptability check method for detection tools according to claim 1, wherein the method, before obtaining the first detection data and obtaining the second detection data, further comprises the step of:
determining whether the detection tool to be checked and existing detection tool are capable of repeatedly detecting a same wafer;
when “yes”, the provided wafers being wafers to be repeatedly detectable, the detection tool to be checked and existing detection tool detecting the same wafer and then obtaining the corresponding first detection data and second detection data; and
when “no”, the provided wafers being wafers to be unrepeatably detectable, the detection tool to be checked and existing detection tool detecting different wafers and then obtaining the corresponding first detection data and second detection data.

3. The acceptability check method for detection tools according to claim 2, wherein the detecting the plurality of wafers comprises:
a first test item in which an alternating current is utilized as a detecting current for electrical parameter detection; and
a second test item in which a direct current is utilized as the detecting current for electrical parameter detection;
wherein the first detection data and the second detection data are test item data of the same test item.

4. The acceptability check method for detection tools according to claim 3, wherein a data analysis method based on fuzzy system models is used as the method for data analysis of the first detection data and the second detection data.

5. The acceptability check method for detection tools according to claim 4, wherein
the procedure of performing data analysis on the first detection data and the second detection data to obtain category classifications corresponding to the first detection data and the second detection data comprises:
dividing the second detection data into a plurality of clusters;
building, according to the plurality of clusters, a fuzzy system model, the fuzzy system model being one of a model α, a model β and a model γ; wherein
the model α comprising three category classifications and three corresponding distribution functions, the three category classifications being a low category, a medium category and a high category,
the model β comprising two category classifications and two corresponding distribution functions, the two category classifications being a slightly lower category and a slightly higher category,
the model γ comprising one category classification and one corresponding distribution function, and the one category classification being an overall category;
projecting the first detection data into the fuzzy system model, so as to obtain the category classification corresponding to the first detection data; and
projecting the second detection data into the fuzzy system model, so as to obtain the category classification corresponding to the second detection data.

6. The acceptability check method for detection tools according to claim 5, wherein the step of obtaining the category classification corresponding to the first detection data and the second detection data comprises:
obtaining the category classification corresponding to each test item data under the first test item and the second test item.

7. The acceptability check method for detection tools according to claim 6, wherein the step of determining whether the first detection data corresponding to the category classification is acceptable comprises:
determining whether each of the test item data under the first test item of the detection tool to be checked is acceptable; and
determining whether each of the test item data under the second test item of the detection tool to be checked is acceptable.

8. The acceptability check method for detection tools according to claim 5, wherein the second detection data are divided into a plurality of clusters using a K-Means clustering algorithm.

9. The acceptability check method for detection tools according to claim 8, wherein the method, before the second detection data are divided into a plurality of clusters, further comprises the step of: determining whether numbers of the first detection data and second detection data are both greater than 10, when “yes”, executing the step of dividing the second detection data into a plurality of clusters, and when “no”, ending the check flow.

10. The acceptability check method for detection tools according to claim 5, wherein the procedure of dividing into a plurality of clusters, building the fuzzy system model and obtaining the category classification corresponding to the first detection data and the second detection data comprises:
when dividing the second detection data into a plurality of clusters, presetting a value K in a K-Means clustering algorithm to be equal to 3, and then dividing the second detection data into 3 clusters through the K-Means clustering algorithm; building, according to the 3 clusters, a fuzzy system model, which is a model α; projecting the first detection data and the second detection data into the model α, respectively, so as to obtain the category classification corresponding to each of the first detection data and the second detection data; determining whether numbers of the first detection data and the second detection data after the category classifications are obtained are both greater than 10, when “yes”, executing the step of determining whether the first detection data corresponding to each category classification of the detection tool to be checked is acceptable, and when “no”, decreasing the value K by 1; then, when the value K is equal to 2, dividing the second detection data into 2 clusters through the K-Means clustering algorithm; building, according to the 2 clusters, a fuzzy system model, which is the model β; projecting the first detection data and the second detection data into the model β, respectively, so as to obtain the category classification corresponding to the first detection data and second detection data; based on the category classification corresponding to the first detection data and second detection data, continuing to determine whether the numbers of the first detection data and second detection data after the category classifications are obtained are both greater than 10, when “yes”, executing the step of determining whether the first detection data corresponding to each category classification of the detection tool to be checked is acceptable, and when “no”, decreasing the value K by 1; dividing the second detection data into 1 cluster through the K-Means clustering algorithm when the value K is equal to 1; building, according to the 1 cluster, a fuzzy system model, which is the model γ; projecting the first detection data and the second detection data into the model γ, respectively, so as to obtain the category classification corresponding to the first detection data and second detection data, and directly executing the step of determining whether the first detection data corresponding to each category classification of the detection tool to be checked is acceptable.

11. The acceptability check method for detection tools according to claim 5, wherein a Student's t test is used to determine whether the first detection data corresponding to category classification is acceptable.

12. The acceptability check method for detection tools according to claim 11, wherein when the detection tool to be checked and existing detection tool detect the same wafer to be detected, a paired sample mean Student's t test is used as the Student's t test.

13. The acceptability check method for detection tools according to claim 11, wherein when the detection tool to be checked and existing detection tool detect different wafers to be detected, an independent sample Student's t test is used as the Student's t test.

14. The acceptability check method for detection tools according to claim 12, wherein a statistical significance level value a is adjusted according to a determination result of whether the first detection data corresponding to category classification is acceptable, and the Student's t test is performed again.

15. An acceptability check system for detection tools, comprising:
a wafer providing circuit, configured to provide a plurality of wafers;
a detection tool to be checked, configured to detect the plurality of wafers in the detection tool to be checked, to obtain several first detection data;
an existing detection tool, configured to detect the plurality of wafers in the existing detection tool, to obtain several second detection data;
a data analyzing circuit, configured to perform data analysis on the first detection data and the second detection data, to obtain category classifications corresponding to the first detection data and the second detection data; and
a determining circuit, configured to determine whether the first detection data corresponding to category classification of the detection tool to be checked is acceptable;
wherein the number of wafers detected using the detection tool to be checked and the number of wafers detected using the existing detection tool are the same.

16. The acceptability check system for detection tools according to claim 15, wherein the system further comprises:
a repeatable detection determining circuit, configured to determine, before the detection tool to be checked obtains the first detection data and the existing detection tool obtains the second detection data, whether the detection tool to be checked and existing detection tool are capable of repeatedly detecting a same wafer, when “yes”, the wafers provided by the wafer providing circuit being wafers to be repeatedly detectable, the detection tool to be checked and existing detection tool detecting the same wafer and then obtaining the corresponding first detection data and second detection data, and when “no”, the wafers provided by the wafer providing circuit being wafers to be unrepeatably detectable, the detection tool to be checked and existing detection tool detecting different wafers and then obtaining the corresponding first detection data and second detection data.

17. The acceptability check system for detection tools according to claim 16, wherein the detecting the plurality of wafers comprises:
a first test item in which an alternating current is utilized as a detecting current for electrical parameter detection; and
a second test item in which a direct current is utilized as the detecting current for electrical parameter detection;
wherein the first detection data and the second detection data are test item data of the same test item.

18. The acceptability check system for detection tools according to claim 17, wherein a data analysis method based on fuzzy system models is used as the method for data analysis of the first detection data and the second detection data by the data analyzing circuit.

19. The acceptability check system for detection tools according to claim 18, wherein the procedure of performing data analysis on the first detection data and the second detection data to obtain category classifications corresponding to the first detection data and the second detection data by the data analyzing circuit comprises:
dividing the second detection data into a plurality of clusters; and
building, according to the clusters, a fuzzy system model, the fuzzy system model being one of a model α, a model β and a model γ; wherein,
the model α comprises three category classifications and three corresponding distribution functions, the three category classifications are a low category, a medium category and a high category,
the model β comprises two category classifications and two corresponding distribution functions, the two category classifications are a slightly lower category and a slightly higher category,
the model γ comprises one category classification and one corresponding distribution function, and the one category classification is an overall category.

20. The acceptability check system for detection tools according to claim 19, wherein a Student's t testis used to determine whether the first detection data corresponding to the category classification is acceptable.
